(19) United States
(12) Patent Application Publication
(10) Pub. No.: US 2011/0062472 A1
(43) Pub. Date: Mar. 17, 2011

(54) WAVELENGTH-CONVERTED SEMICONDUCTOR LIGHT EMITTING DEVICE

(75) Inventor: Oleg B. SHCHEKIN, San Francisco, CA (US)

(73) Assignees: KONINKLIJKE PHILIPS ELECTRONICS N.V., EINDHOVEN (NL); PHILIPS LUMILEDS LIGHTING COMPANY, LLC, SAN JOSE, CA (US)

(21) Appl. No.: 12/561,759

(22) Filed: Sep. 17, 2009

(51) Int. Cl. H01L 33/00

(52) U.S. Cl. 257/98; 257/E33.061; 257/E33.067

(57) ABSTRACT

A light emitting diode includes a semiconductor structure comprising a light emitting layer disposed between an n-type region and a p-type region, and n- and p-contacts disposed on the n- and p-type regions. The light emitting layer is configured to emit light of a first peak wavelength. A wavelength converting material is positioned in a path of light emitted by the light emitting layer. The wavelength converting material is configured to absorb light of the first peak wavelength and emit light of a second peak wavelength. The light emitting diode is configured such that a light emission pattern from the light emitting diode complements a light emission pattern from the wavelength converting material.

### FIELD OF INVENTION

The present invention relates to a wavelength-converted semiconductor light emitting device.

### BACKGROUND

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a sapphire, silicon carbide, III-nitride, composite, or other suitable substrate by metal-organic chemical vapor deposition (MOCVD), molecular beam epitaxy (MBE), or other epitaxial techniques. The stack often includes one or more n-type layers doped with, for example, Si, formed over the substrate, one or more light emitting layers in an active region formed over the n-type layer or layers, and one or more p-type layers doped with, for example, Mg, formed over the active region. Electrical contacts are formed on the n- and p-type regions. III-nitride devices are often formed as inverted or flip chip devices, where both the n- and p-contacts formed on the same side of the semiconductor structure, and light is extracted from the side of the semiconductor structure opposite the contacts.

The structure of a semiconductor light emitting device may be designed to influence the radiation pattern emitted by the device and to enhance the extraction of light from the device. Two techniques for influencing the radiation pattern emitted by the device are forming a photonic crystal structure in the device, and selecting the spacing between a reflective surface and the center of the light emitting region in the device.

Forming a photonic crystal structure is described in more detail in U.S. Pat. No. 7,012,279, which is incorporated herein by reference. The photonic crystal structure can include a periodic variation of the thickness of a semiconductor layer in the device, with alternating maxima and minima. An example is a planar lattice of holes. The lattice is characterized by the diameter of the holes, d, the lattice constant a, which measures the distance between the centers of nearest neighbor holes, the depth of the holes w, and the dielectric constant of the dielectric disposed in the holes, ∈ₕ. Parameters a, d, w, and ∈ₕ influence the density of states of the bands, and in particular, the density of states at the band edges of the photonic crystal's spectrum. Parameters a, d, w, and ∈ₕ thus influence the radiation pattern emitted by the device, and can be selected to enhance the extraction efficiency from the device.

The holes can have circular, square, hexagonal, or other cross sections. The lattice spacing a may be between about 0.1λ and about 10λ, preferably between about 0.1λ and about 4λ, where λ is the wavelength in the device of light emitted by the active region. The holes may have a diameter d between about 0.1 a and about 0.5 a, where a is the lattice constant, and a depth w between zero and the full thickness of the semiconductor structure in which the photonic crystal structure is formed. The holes may have a depth between about 0.05λ and about 5λ. The depth of the holes may be selected to place the bottoms of the holes as close to the active region as possible, without penetrating layers which may cause problems such as type conversion. The holes can be filled with air or with a dielectric of dielectric constant ∈ₕ, often between about 1 and about 16. Possible dielectrics include silicon oxides.

Influencing the radiation pattern by selecting the spacing between a reflective surface and the center of the light emitting region is described in more detail in U.S. Pat. No. 6,903,376, which is incorporated herein by reference. Beginning at column 14, line 24, U.S. Pat. No. 6,903,376 recites: “Light extraction efficiency may be further improved by placing the active region layers near the highly reflective p-electrode. Assuming the p-electrode is a perfectly conducting metal, when the center of the active region is brought within approximately an odd multiple of quarter-wavelengths of light within the material (˜λ/4n) from the reflective p-electrode, constructive interference of the downward and upward traveling light results in a radiation pattern that emits power preferentially in the upward direction. This enhancement is in a direction close to normal to the III-nitride/substrate and is not susceptible to total internal reflection back into the III-nitride epi layers. Alternatively, slight detuning of the resonance condition, by moving the active region slightly closer to (or farther from) the p-electrode reflector, may be preferred to optimize the light extraction improvement for total flux in all directions. For maximum efficiency in most applications, the distance between the active region and a perfectly conducting metal p-electrode should be approximately one quarter-wavelength.

“Further retuning of the resonance condition for maximum extraction in a device with a nonideal metal contact depends on the phase shift of light reflecting off the metal. Methods for determining the phase shift of an actual reflective contact, then determining the optimal placement of an active region relative to that contact based on the phase shift are described” in U.S. Pat. No. 6,903,376.

### SUMMARY

It is an object of the invention to provide a light emitting diode configured such that the light emission pattern from the light emitting diode complements the light emission pattern from a wavelength converting material disposed in the path of light emitted by the light emitting diode.

Embodiments of the invention include a light emitting diode comprising a semiconductor structure including a light emitting layer disposed between an n-type region and a p-type region, and n- and p-contacts disposed on the n- and p-type regions. The light emitting layer is configured to emit light of a first peak wavelength. A wavelength converting material is positioned in a path of light emitted by the light emitting layer. The wavelength converting material is configured to absorb light of the first peak wavelength and emit light of a second peak wavelength. The light emitting diode is configured such that a light emission pattern from the light emitting diode complements a light emission pattern from the wavelength converting material. In some embodiments, the light emitting diode includes a photonic crystal structure configured such that the light emission pattern from the light emitting diode complements the light emission pattern from the wavelength converting material. In some embodiments, the spacing between a reflective surface in the light emitting diode and a center of the light emitting layer is configured such that the light emission pattern from the light emitting diode complements the light emission pattern from the wavelength converting material.

### BRIEF DESCRIPTION OF THE DRAWINGS

FIG. 1 illustrates a III-nitride light emitting device connected to a mount, with the growth substrate removed and with a wavelength converting material disposed over the semiconductor layers.

FIG. 2 is a plot of power as a function of angle for the blue and yellow emission of a wavelength-converted III-nitride light emitting device.

FIG. 3 is a plot of power as a function of angle for the blue emission of two wavelength-converted III-nitride light emitting devices.

FIG. 4 is a plot, for two wavelength-converted III-nitride light emitting devices, of the ratio of emitted yellow light to emitted blue light, normalized to their values at zero angle, as a function of angle.

### DETAILED DESCRIPTION

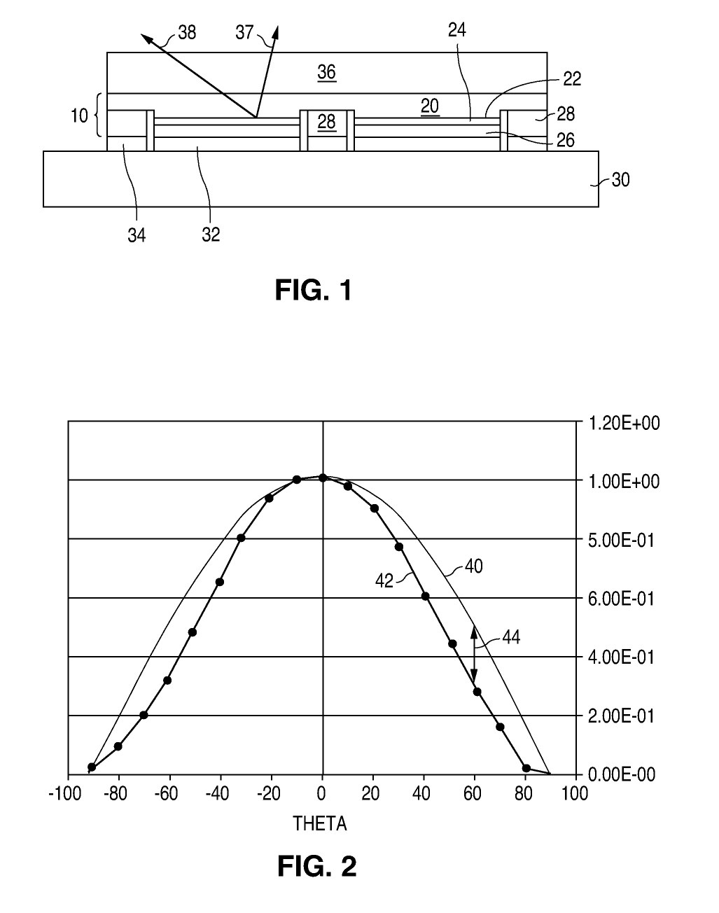

FIG. 1 illustrates a III-nitride light emitting device. A III-nitride semiconductor structure including an n-type region, a light emitting or active region, and a p-type region is grown over a growth substrate (not shown), which may be any suitable growth substrate and which is typically sapphire or SiC. An n-type region 20 is grown first over the substrate. The n-type region may include multiple layers of different compositions and dopant concentration including, for example, preparation layers such as buffer layers or nucleation layers, which may be n-type or not intentionally doped, release layers designed to facilitate later release of the growth substrate or thinning of the semiconductor structure after substrate removal, and n- or even p-type device layers designed for particular optical or electrical properties desirable for the light emitting region to efficiently emit light.

A light emitting or active region 22 is grown over the n-type region 20. Examples of suitable light emitting regions include a single thick or thin light emitting layer, or a multiple quantum well light emitting region including multiple thin or thick quantum well light emitting layers separated by barrier layers. For example, a multiple quantum well light emitting region may include multiple light emitting layers, each with a thickness of 25 Å or less, separated by barriers, each with a thickness of 100 Å or less. In some embodiments, the thickness of each of the light emitting layers in the device is thicker than 50 Å.

A p-type region 24 is grown over the light emitting region 22. Like the n-type region, the p-type region may include multiple layers of different composition, thickness, and dopant concentration, including layers that are not intentionally doped, or n-type layers.

A reflective metal p-contact 26 is formed on p-type region 24. Portions of the p-contact 26, p-type region 24, and light emitting region 22 are etched away to expose portions of the n-type region 20. N-contacts 28 are formed on the exposed portions of the n-type region.

LED 10 is bonded to mount 30 by n- and p-interconnects 34 and 32. Interconnects 32 and 34 may be any suitable material, such as solder or other metals, and may include multiple layers of materials. In some embodiments, interconnects include at least one gold layer and the bond between LED 10 and mount 30 is formed by ultrasonic bonding.

During ultrasonic bonding, the LED die 10 is positioned on the mount 30. A bond head is positioned on the top surface of the LED die, often the top surface of a sapphire growth substrate in the case of a III-nitride device grown on sapphire. The bond head is connected to an ultrasonic transducer. The ultrasonic transducer may be, for example, a stack of lead zirconate titanate (PZT) layers. When a voltage is applied to the transducer at a frequency that causes the system to resonate harmonically (often a frequency on the order of tens or hundreds of kHz), the transducer begins to vibrate, which in turn causes the bond head and the LED die to vibrate, often at an amplitude on the order of microns. The vibration causes atoms in the metal lattice of a structure on the LED 10, such as the n- and p-contacts or a metal layer formed on the n- and p-contacts, to interdiffuse with a structure on mount 30, resulting in a metallurgically continuous joint represented in FIG. 1 by interconnects 34 and 32. Heat and/or pressure may be added during bonding.

After bonding LED die 10 to mount 30, all or part of the substrate on which the semiconductor layers were grown may be removed by any technique suitable to the particular growth substrate removed. For example, a sapphire substrate may be removed by laser lift off After removing all or part of the growth substrate, the remaining semiconductor structure may be thinned, for example by photoelectrochemical etching, and/or the surface may be roughened or patterned, for example with a photonic crystal structure.

A wavelength converting material 36, which absorbs light emitted by light emitting region 22 and emits light of one or more different peak wavelengths, is disposed over LED 10. Wavelength converting material 36 may be, for example, one or more powder phosphors disposed in a transparent material such as silicone or epoxy and deposited on LED 10 by screen printing or stenciling, one or more powder phosphors formed by electrophoretic deposition, or one or more ceramic phosphors glued or bonded to LED 10, one or more dyes, or any combination of the above-described wavelength converting layers. Ceramic phosphors are described in more detail in U.S. Pat. No. 7,361,938, which is incorporated herein by reference. Wavelength converting material 36 may be formed such that a portion of light emitted by light emitting region 22 is unconverted by the wavelength converting material 36. In some examples, the unconverted light is blue and the converted light is yellow, green, and/or red, such that the combination of unconverted and converted light emitted from the device appears white.

In the device illustrated in FIG. 1, the color appearance of the combined light may vary as a function of viewing angle. Depending on the angle of incidence of light emitted by the light emitting region, the light will take trajectories of different length through wavelength converting material 36. Light that takes a long trajectory through wavelength converting material 36, such as light ray 38 illustrated in FIG. 1, is more likely to be converted; light taking a short trajectory through wavelength converting material 36, such as light ray 37 illustrated in FIG. 1, is less likely to be converted. As a result, when viewed from above, light emitted from the device illustrated in FIG. 1 may appear more yellow in the direction of ray 38, and more blue in the direction of ray 37. Ceramic phosphor wavelength converting layers are particularly susceptible to color vs. angle variation when highly transparent (i.e. non-scattering) luminescent ceramics are used.

FIG. 2 is a plot of measured power as a function of emission angle relative to a normal to the top surface of a device as illustrated in FIG. 1. In the device illustrated in FIG. 2, the light emitting region emits blue light and the wavelength converting material is a cerium doped YAG (Y₃Al₅O₁₂) ceramic phosphor, which emits yellow light. Curve 42 represents the blue light emitted from the device and curve 40 represents the yellow light emitted from the device. In the device illustrated in FIG. 2, the spacing between the reflective silver p-contact and the center of the light emitting region, referred to as d_{c}, is selected to be 0.67λ, a value that concentrates light emission in the top escape cone, as described in more detail in U.S. Pat. No. 6,903,376. As illustrated in FIG. 2, at large emission angles relative to a normal to the top surface of the device, such as at points 44 in the illustrated curves, far more yellow light is emitted than blue light, resulting in the yellow halo described above.

The light emission pattern from wavelength converting material 36 typically depends on the volume, shape, and surface optical properties of the wavelength converting material 36. The light emission pattern from a ceramic phosphor wavelength converting material 36 is generally Lambertian. In embodiments of the invention, the light emission pattern of LED 10 is tuned to add a larger fraction of emitted light in the direction of ray 38 to compensate for the higher probability of down-conversion of the light by the wavelength converting material 36 in the direction. The goal is to match the light emission pattern of the wavelength converting material 36 to the radiation pattern from LED 10 which is not converted by the wavelength converting material 36, to reduce or eliminate the variations in the color appearance of combined unconverted and wavelength-converted light emitted by the device. In some embodiments, a photonic crystal structure which tailors the light emission pattern of LED 10 to match the light emission pattern of wavelength converting material 36 is included in the III-nitride structure of the device, often in the n-type region exposed by removing the growth substrate. In some embodiments, the spacing between the reflective p-contact and the light emitting region is selected to tailor the light emission pattern of LED 10 to match the light emission pattern of wavelength converting material 36.

In some embodiments of the invention, in the device illustrated in FIG. 1, the surface of the n-type region exposed by removing the growth substrate is roughened. The light emitting region emits blue light. The spacing d_{c} between the reflective silver p-contact and the physical center of the light emitting region is between 0.75λ and 0.85λ in some embodiments, 0λ in some embodiments. Wavelength converting material 36 is a cerium-doped YAG ceramic phosphor which emits yellow light. The ceramic phosphor is nearly transparent, such that unconverted light passing through the ceramic phosphor is scattered as little as possible. The sides of the semiconductor structure and the ceramic phosphor are coated with a reflective material, to prevent light from being emitted from the sides. The ceramic phosphor is attached to the semiconductor structure by optically clear thermoplastic with a refractive index of about 1.7.

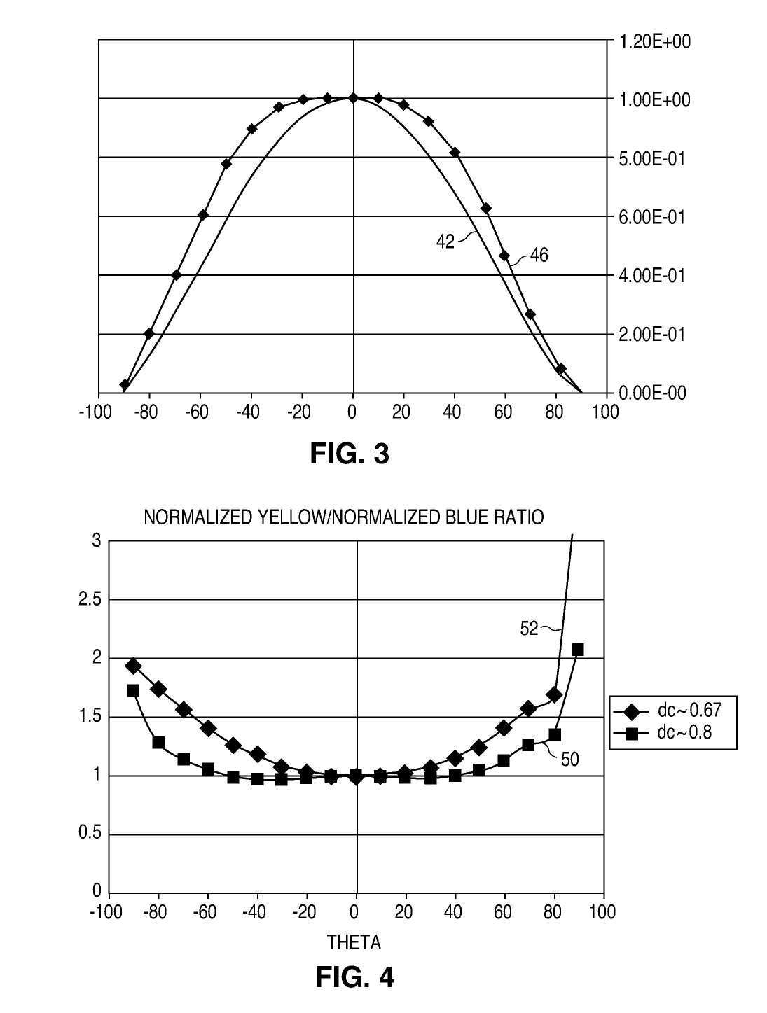

FIG. 3 is a plot of power as a function of emission angle for the blue light emitted by a conventional device as illustrated in FIG. 2, where d_{c}=0.67λ, and the device according to embodiments of the invention described above, where d_{c}=0.8λ. The blue emission of the conventional device where d_{c}=0.67λ is represented by curve 42. The blue emission of the device where d_{c}=0.8λ is represented by curve 46. As illustrated in FIG. 3, the device where d_{c}=0.8λ has more blue emission at large emission angles relative to a normal to the top surface of the device, for example at emission angles between 40° and 80°. The increased blue emission at large angles balances the higher degree of down-conversion at large angles illustrated in FIG. 2.

FIG. 4 is a plot of the ratio of intensity of yellow light emitted to intensity of blue light emitted, normalized to their values at zero angle, as a function of angle for the two devices illustrated in FIG. 3. The ratio of yellow light to blue light for the conventional device where d_{c}=0.67λ is represented by curve 52. The ratio of yellow light to blue light for the device according to embodiments of the invention where d_{c}=0.8λ is represented by curve 50. As illustrated in FIG. 4, in the device where d_{c} is selected to compensate for the higher probability of down-conversion of the light traveling at higher azimuth angles by the wavelength converting material 36 (i.e., the device where d_{c}=0.8λ), the variation in yellow-to-blue ratio over angle is much less than the variation in yellow-to-blue ratio in the conventional device where d_{c} is selected to maximize emission in a top escape cone (i.e., the device where d_{c}=0.67λ).

As illustrated in FIG. 4, at emission angles between 0° and 50° in the device where d_{c}=0.8λ, the ratio of yellow to blue emitted light varies between about 0.95 and 1, less than about 5%. At emission angles between 0° and 50° in the device where d_{c}=0.67λ, the ratio of yellow to blue emitted light varies between 1 and about 1.25, less than about 25%. At emission angles between 0° and 50°, in devices according to embodiments of the invention where the light emission pattern of LED 10 is tuned to compensate for the higher probability of down-conversion of the light traveling at higher azimuth angles by the wavelength converting material 36, the ratio of yellow emitted light to blue emitted light varies less than 15% in some embodiments, less than 10% in some embodiments, and less than 5% in some embodiments. At emission angles between 0° and 50°, in devices according to embodiments of the invention where the light emission pattern of LED 10 is tuned to compensate for the higher probability of down-conversion of the light traveling at higher azimuth angles by the wavelength converting material 36, the ratio of yellow emitted light to blue emitted light is greater than 0.9 and less 1.1 in some embodiments.

As illustrated in FIG. 4, at emission angles between 0° and 80° in the device where d_{c}=0.67λ, the ratio of yellow to blue emitted light varies between 1 and about 1.7, less than about 70%. At emission angles between 0° and 80° in the device where d_{c}=0.8λ, the ratio of yellow to blue emitted light varies between 1 and about 1.35, less than about 35%. At emission angles between 0° and 80°, in devices according to embodiments of the invention where the light emission pattern of LED 10 is tuned to compensate for the higher probability of down-conversion of the light traveling at higher azimuth angles by the wavelength converting material 36, the ratio of yellow emitted light to blue emitted light varies less than 50% in some embodiments, less than 40% in some embodiments, and less than 35% in some embodiments. At emission angles between 0° and 80°, in devices according to embodiments of the invention where the light emission pattern of LED 10 is tuned to compensate for the higher probability of down-conversion of the light traveling at higher azimuth angles through the wavelength converting material 36, the ratio of yellow emitted light to blue emitted light is greater than 0.9 and less than 1.4 in some embodiments.

Having described the invention in detail, those skilled in the art will appreciate that, given the present disclosure, modifications may be made to the invention without departing from the spirit of the inventive concept described herein. For example, though the examples above are III-nitride devices, embodiments of the invention may be implemented in other semiconductor light emitting devices such as other III-V devices, III-phosphide and III-arsenide devices, and II-VI devices. Additionally, embodiments of the invention are also applicable to conventional phosphor solutions comprised of powder phosphors dispersed in organic matrices, and to LED structures other than flip chips such as vertical injection thin film LEDs, where a p-contact is formed on the p-type region, the III-nitride structure is connected to a mount through the p-contact, the growth substrate is removed, and an n-contact is formed on the n-type region exposed by removing the growth substrate. Therefore, it is not intended that the scope of the invention be limited to the specific embodiments illustrated and described.

What is being claimed is:

1. A device comprising:
a light emitting diode comprising:
semiconductor structure comprising a light emitting layer disposed between an n-type region and a p-type region, the light emitting layer being configured to emit light of a first peak wavelength; and
n- and p-contacts disposed on the n- and p-type regions; and
a wavelength converting material positioned in a path of light emitted by the light emitting layer, the wavelength converting material being configured to absorb light of the first peak wavelength and emit light of a second peak wavelength;
wherein the light emitting diode is configured such that a light emission pattern from the light emitting diode complements a light emission pattern from the wavelength converting material.

2. The device of claim 1 wherein the light emitting diode is configured such that at emission angles relative to a normal to a top surface of the device between 0° and 50°, a ratio of light emitted by the wavelength converting material normalized to a value at 0° to unconverted light emitted by the light emitting layer normalized to a value at 0° varies less than 15%.

3. The device of claim 1 wherein the light emitting diode is configured such that at emission angles relative to a normal to a top surface of the device between 0° and 50°, a ratio of light emitted by the wavelength converting material normalized to a value at 0° to unconverted light emitted by the light emitting layer normalized to a value at 0° varies less than 10%.

4. The device of claim 1 wherein the light emitting diode is configured such that at emission angles relative to a normal to a top surface of the device between 0° and 50°, a ratio of light emitted by the wavelength converting material normalized to a value at 0° to unconverted light emitted by the light emitting layer normalized to a value at 0° is less than 1.2.

5. The device of claim 1 wherein the light emitting diode is configured such that at emission angles relative to a normal to a top surface of the device between 0° and 80°, a ratio of light emitted by the wavelength converting material normalized to a value at 0° to unconverted light emitted by the light emitting layer normalized to a value at 0° varies less than 50%.

6. The device of claim 1 wherein the light emitting diode is configured such that at emission angles relative to a normal to a top surface of the device between 0° and 80°, a ratio of light emitted by the wavelength converting material normalized to a value at 0° to unconverted light emitted by the light emitting layer normalized to a value at 0° is less than 1.5.

7. The device of claim 1 wherein the n- and p-contacts are formed on a bottom surface of the semiconductor structure, the light emitting diode further comprising a photonic crystal formed in a top surface of the semiconductor structure.

8. The device of claim 7 wherein the photonic crystal is configured such that a light emission pattern from the light emitting diode complements a light emission pattern from the wavelength converting material.

9. The device of claim 1 wherein:
the light emitting diode further comprises a reflective surface; and
a spacing between the reflective surface and a center of the light emitting layer is configured such that a light emission pattern from the light emitting diode complements a light emission pattern from the wavelength converting material.

10. The device of claim 1 wherein:
the p-contact comprises silver; and
a spacing between a physical center of the light emitting layer and an interface between the p-contact and the p-type region is between 0.75λ and 0.85λ, where λ is the first peak wavelength in the light emitting diode.

11. The device of claim 1 wherein the wavelength converting material comprises a ceramic phosphor.

12. The device of claim 1 wherein the wavelength converting material comprises a powder phosphor disposed in a transparent material.
